(19) United States
(12) Patent Application Publication
(10) Pub. No.: US 2011/0212403 A1
(43) Pub. Date: Sep. 1, 2011

(54) METHOD AND APPARATUS FOR ENHANCED DIPOLE LITHOGRAPHY

(75) Inventors: Ming-Jhih Kuo, Zhubei City (TW); Chun-Kuang Chen, Hsin-Chu Hsien (TW); Ya Hui Chang, Hsinchu City (TW); Tommy Kuo, Zhubei City (TW); Hsien-Cheng Wang, Hsinchu (TW); Ko-Bin Kao, Shengang Township (TW)

(73) Assignee: TAIWAN SEMICONDUCTOR MANUFACTURING COMPANY, LTD., Hsin-Chu (TW)

(21) Appl. No.: 12/713,335

(22) Filed: Feb. 26, 2010

(51) Int. Cl. G03F 7/20; G03B 27/54

(52) U.S. Cl. 430/322; 355/67

(57) ABSTRACT

Provided is a lithography system that includes a source for providing energy, an imaging system configured to direct the energy onto a substrate to form an image thereon, and a diffractive optical element (DOE) incorporated with the imaging system, the DOE having a first dipole located in a first direction and a second dipole located in the first direction or a second direction perpendicular the first direction. The first dipole includes a first energy-transmitting region spaced a first distance from a center of the DOE. The second dipole includes a second energy-transmitting region spaced a second distance from the center of the DOE. The first distance is greater than the second distance.

### BACKGROUND

Semiconductor integrated circuit (IC) technology has experienced rapid progress including the continued minimization of feature sizes and the maximization of packing density. The minimization of feature size relies on improvement in photolithography and its ability to print smaller features or critical dimensions (CD). One approach utilizes a diffractive optical element (DOE) with a strong off-axis illumination to achieve high resolution and to control CD uniformity for a dense pattern of features. However, the integrated circuit may also include an isolated pattern of features formed on the same mask. Accordingly, a diffractive optical element (DOE) that is suitable for the dense pattern may not be suitable for the isolated pattern which can lead to defects such as photoresist residual defects.

### SUMMARY

One of the broader forms of an embodiment of the present invention involves a lithography system. The lithography system includes a source for providing energy; an imaging system configured to direct the energy onto a substrate to form an image thereon; and a diffractive optical element (DOE) incorporated with the imaging system, the DOE having a first dipole located in a first direction and a second dipole located in one of the first direction and a second direction perpendicular the first direction. The first dipole includes a first energy-transmitting region spaced a first distance from a center of the DOE. The second dipole includes a second energy-transmitting region spaced a second distance from the center of the DOE, wherein the first distance is greater than the second distance.

Another one of the broader forms of an embodiment of the present invention involves a lithography exposure method. The lithography exposure method includes providing a lithography system that includes: a source for providing energy; an imaging system configured to direct the energy onto a substrate; and a diffractive optical element (DOE) incorporated with the imaging system, the DOE having a first dipole located in a first direction and a second dipole located in one of the first direction and a second direction perpendicular the first direction, wherein the first dipole includes a first energy-transmitting region spaced a first distance from a center of the DOE, wherein the second dipole includes a second energy-transmitting region spaced a second distance from the center of the DOE, wherein the first distance is greater than the second distance; aligning a photomask with the substrate; and performing an exposure process with the lithography system such that an image of the photomask is transferred onto the substrate.

Yet another one of the broader forms of an embodiment of the present invention involves a method for lithography processing in a lithography system. The method includes providing a photomask having a first region and a second region, the first region including a dense pattern of features with a pitch not less than 80 nm, the second region including an isolated pattern of features with a spacing ranging from about 60 nm to about 200 nm; and performing an exposure process with the lithography system to transfer the dense pattern of features and the isolated pattern of features onto a substrate. The exposure process includes one of: a single exposure process with a dual dipole diffractive optical element (DOE) having a first dipole structure aligned in a first direction and a second dipole structure aligned in one of the first direction and a second direction perpendicular the first direction; and a double exposure process including a first exposure with a first single dipole DOE having one of the first dipole structure and the second dipole structure and a second exposure process with a second single dipole DOE having the other one of the first dipole structure and the second dipole structure.

### BRIEF DESCRIPTION OF THE DRAWINGS

The present disclosure is best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a schematic view of an exemplary embodiment of a lithography system according to various aspects of the present disclosure;

FIG. 2 is a top view of an exemplary embodiment of a photomask that can be exposed using the lithography system of FIG. 1;

FIG. 3 is a diagrammatic representation of positions of radiation-transmitting regions of a diffractive optical element according to various aspects of the present disclosure;

FIGS. 4-6 are schematic views of various exemplary embodiments of a diffractive optical element (DOE) that can be incorporated in the lithography system of FIG. 1;

FIG. 7 is a flow chart of an exemplary method for patterning a substrate according to various aspects of the present disclosure;

FIG. 8 is a diagrammatic representation illustrating the method of FIG. 7;

FIG. 9 is a flow chart of another exemplary method for patterning a substrate according to various aspects of the present disclosure; and

FIG. 10 is a diagrammatic representation illustrating the method of FIG. 9.

### DETAILED DESCRIPTION

It is understood that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

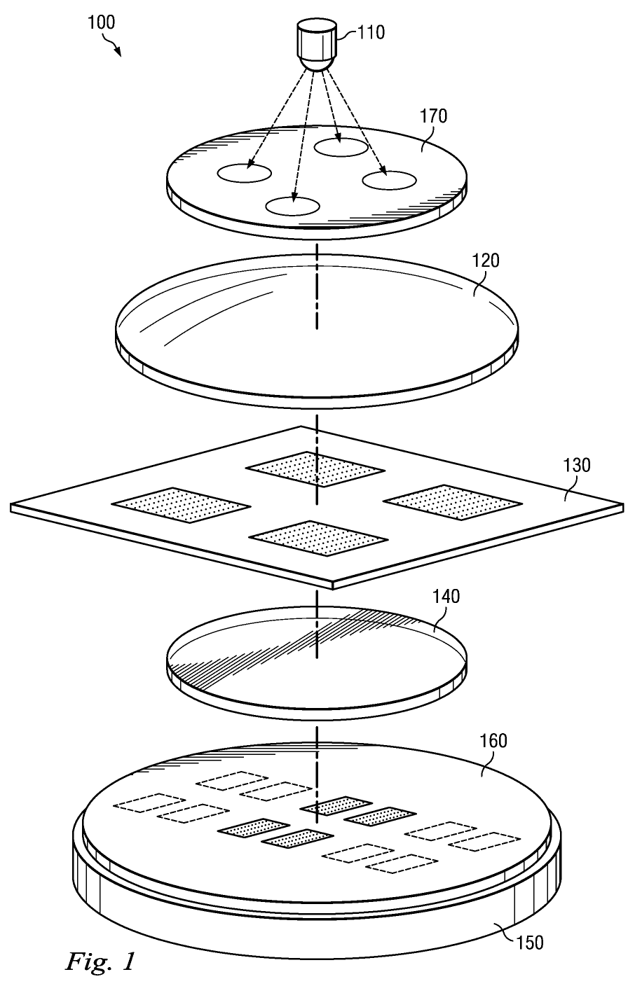

Referring to FIG. 1, in one embodiment, a lithography system 100 includes a radiation source (or source) 110. The radiation source 110 may be any suitable light source. For example, the source 110 may be a mercury lamp having a wavelength of 436 nm (G-line) or 365 nm (I-line); a Krypton Fluoride (KrF) excimer laser with wavelength of 248 nm; an Argon Fluoride (ArF) excimer laser with a wavelength of 193 nm; a Fluoride (F₂) excimer laser with a wavelength of 157 nm; or other light sources having a desired wavelength (e.g., below approximately 100 nm). The radiation source 110 may include an optical source selected from the group consisting of ultraviolet (UV) source, deep UV (DUV) source, extreme UV (EUV) source, and X-ray source. The radiation source 110 may alternatively include a particle source selected from the group consisting of electron beam (E-Beam) source, ion beam source, and plasma source.

It is understood that each light source may have a certain wavelength distribution, or line width, rather than an exact single wavelength. For example, the I-line (e.g., 365 nm) wavelength of the mercury lamp may not be exactly 365 nm, but may be centered at approximately 365 nm with a range of varying wavelengths extending above and below 365 nm. This range may be used to determine a minimum possible line width during photolithography, with less variation from the desired 365 nm wavelength resulting in a thinner line width.

The lithography system 100 further includes an illumination system (e.g., a condenser) 120. The illumination system 120 may comprise a single lens or a lens system having multiple lenses and/or other lens components. For example, the illumination system 120 may include microlens arrays, shadow masks, and/or other structures designed to aid in directing light from the light source 110 onto a photomask.

During a lithography patterning process, a photomask (also referred to as a mask or a reticle) 130 may be included in the lithography system 100. The photomask 130 includes a transparent substrate and a patterned absorption layer. The transparent substrate may use fused silica (SiO₂) relatively free of defects, such as borosilicate glass and soda-lime glass. The transparent substrate may use calcium fluoride and/or other suitable materials. The patterned absorption layer may be formed using a plurality of processes and a plurality of materials, such as depositing a metal film made with chromium (Cr) and iron oxide, or an inorganic film made with MoSi, ZrSiO, SiN, and/or TiN. A light beam may be partially or completely blocked when directed on an absorption region. The absorption layer may be patterned to have one or more openings through which a light beam may travel without being absorbed by the absorption layer. The mask may incorporate other resolution enhancement techniques such as phase shift mask (PSM) and/or optical proximity correction (OPC).

The lithography system 100 further includes an objective lens 140. The objective lens 140 may have a single lens element or a plurality of lens elements. Each lens element may include a transparent substrate and may further include a plurality of coating layers. The transparent substrate may be a conventional objective lens, and may be made of fused silica (SiO₂), calcium-fluoride (CaF₂), lithium fluoride (LiF), barium fluoride (BaF₂), or other suitable material. The materials used for each lens element may be chosen based on the wavelength of light used in the lithography process to minimize absorption and scattering. The illumination lens 120 and the objective lens 140 are collectively referred to as an imaging lens. The imaging lens may further include additional components such as an entrance pupil and an exit pupil to form an image defined in the photomask 130 on a substrate to be patterned.

The lithography system 100 further includes a substrate stage 150 for securing and moving a substrate in translational and rotational modes such that the substrate may be aligned with the photomask 130. In the present example, a substrate 160 may be provided in the lithography system 100 for receiving a lithography process. The substrate 160 may be a semiconductor wafer comprising an elementary semiconductor such as crystal silicon, polycrystalline silicon, amorphous silicon, germanium, and diamond, a compound semiconductor such as silicon carbide and gallium arsenic, an alloy semiconductor such as SiGe, GaAsP, AlinAs, AlGaAs, and GaInP, or any combination thereof. The substrate 160 may also have a photoresist coating layer formed thereon during the lithography process.

The lithography system 100 includes a diffractive optical element (DOE) 170 (also referred to as an aperture) having a plurality of radiation-transmitting regions (or illumination poles) to transmit radiation energy from the radiation source 110. The DOE 170 may be designed as a dual dipole structure including an extreme dipole structure and an ancillary dipole structure as will be explained in detail below. The DOE 170 may be positioned between the radiation source 110 and the condenser 120 in the lithography system 100 and the plurality of radiation-transmitting regions are defined along radial axis perpendicular to the optical axis. The radiation-transmitting region may be designed to be in various shapes, sizes, and/or be disposed away from the optical axis for off-axis illumination. The radiation-transmitting regions may be further designed to have various radiation intensities, radiation wave phases (such as optical phase), radiation polarizations (such as optical polarization), or combinations thereof utilized by various methods and materials including but not limited to: glass with a tunable tilt angle; multicoated glass with predefined transmittance; two optical polarizers stacked with a specific angle between polarizing directions thereof; liquid crystal sandwiched between two polarizers (parallel or orthogonal) controllable to tune intensity, phase, polarization, or combinations thereof when properly integrated with electrodes; or controllable radiation-blocking mechanisms having various structures such as a window blind structure or a camera shutter.

The lithography system 100 may also incorporate other techniques and components. For example, the lithography system may also include components and mechanism to implement an immersion lithography process.

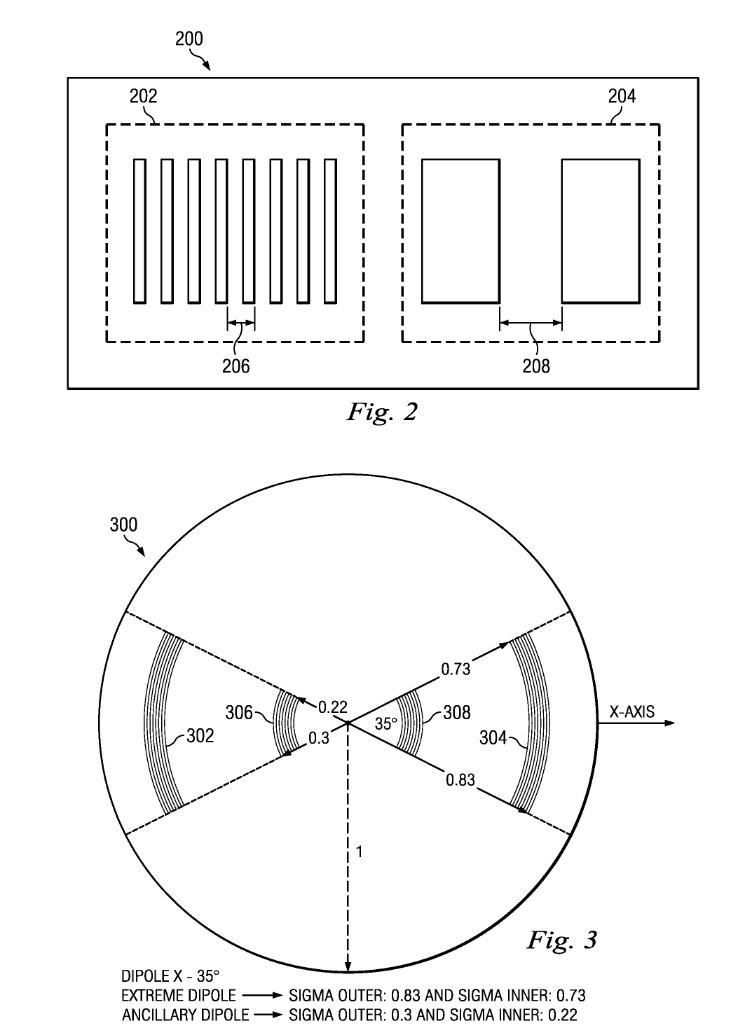

Referring to FIG. 2, illustrated is a photomask 200 that may be used in a lithography process according to an embodiment of the present disclosure. The photomask 200 is similar to the photomask 130 shown in FIG. 2. The photomask 200 includes patterns that form features of an integrated circuit. The photomask 200 includes a region 202 with a dense pattern of features and a region 204 with an isolated pattern of features. For example, the region 202 includes a large number of main features (e.g., poly gates) that are densely packed. In contrast, the region 204 may be an isolated region with a substantially less number of assist features. In an embodiment, the region 202 may include a pattern of parallel features with a pitch 206 ranging from about 80 nm to 90 nm or more for advance technology node processes such as 22 nm and beyond. The region 204 may include assist features that are spaced a distance 208 ranging from about 60 nm to about 200 nm. It has been observed that a DOE with an extreme dipole (strong off-axis illumination) is suitable to properly print and control CD uniformity of the dense pattern in region 202 but suffers defects for the isolated pattern in region 204. These defects include photoresist residual defects resulting from a decreased intensity of the exposure energy. Thus, this may cause design rule constraints on the pattern layout of the photomask. The discussion below illustrates various embodiments of DOEs that have an extreme dipole (high sigma value) plus an ancillary dipole (low sigma value) to address the photoresist residual problem while maintaining proper resolution and CD uniformity control.

Referring to FIG. 3, illustrated is a diagrammatic representation 300 of positions of radiation-transmitting regions of a diffractive optical element (DOE). A DOE includes radiation-transmitting regions 302, 304, 306, 308 that are defined along a radial axis perpendicular to the optical axis at a center 310. In the present embodiment, the radiation-transmitting regions 302, 304, 306, and 308 are positioned corresponding to an outer sigma value and inner sigma value. The DOE may include an extreme dipole with radiation-transmitting regions 302 and 304, and an ancillary dipole with radiation-transmitting regions 306 and 308. The extreme dipole and the ancillary dipole are located on the x-axis. In the present embodiment, the radiation-transmitting regions 302-308 are located with respect to an x-dipole at angle of about 35°. The extreme dipole has sigma values that are greater than the sigma values of the ancillary dipole. The outer and inner sigma values determine a position of the radiation-transmitting region from the center 310 (optical axis) relative to a radius of 1 unit. The inner sigma corresponds to an inner portion of the radiation-transmitting region and the outer sigma corresponds to an outer portion of the radiation-transmitting region. In the present embodiment, the radiation-transmitting regions 302 and 304 (extreme dipole) have an outer sigma of about 0.83 and an inner sigma of about 0.73. The radiation-transmitting regions 306 and 308 have an outer sigma of about 0.30 and an inner sigma of about 0.22. Accordingly, the position of the radiation-transmitting regions of a dipole may be specified by its outer and inner sigma values as discussed below.

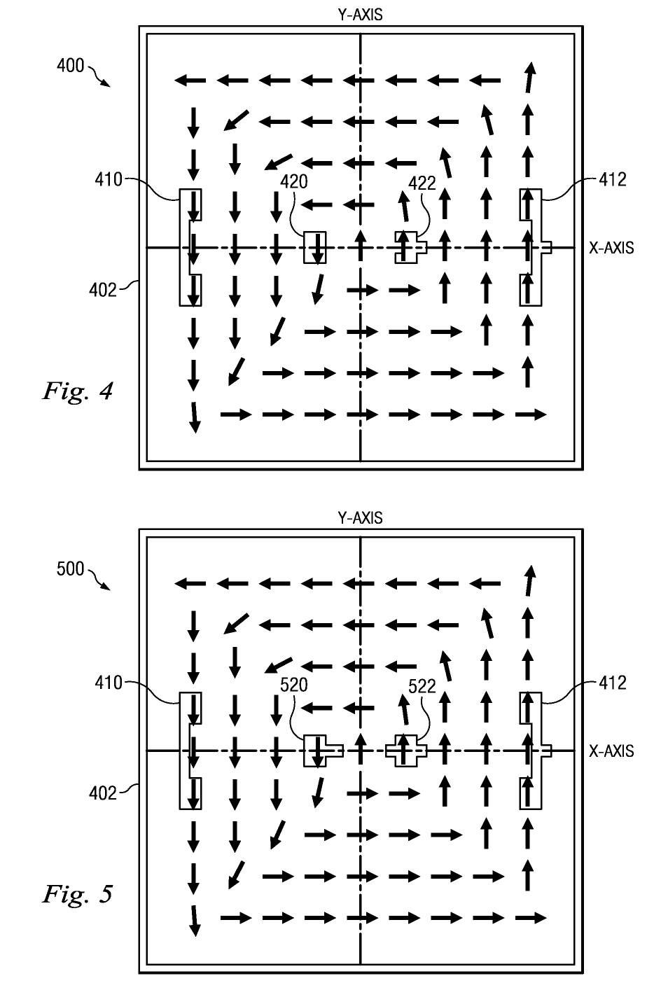

Referring FIG. 4, illustrated is an exemplary embodiment of an DOE 400 that can be incorporated in the lithography system 100 of FIG. 1. The DOE 400 is configured as a dual dipole structure having an extreme dipole and an ancillary dipole located on the x-axis (e.g., x-dipole at an angle of about 35°). The DOE 400 includes a plate 402 being opaque to the radiation so that the radiation illuminated on the plate 402 will be blocked. The plate 402 may be made of a metal, metal alloy, or other proper material. The plate 402 may include proper coating materials. The plate 402 may have a center to be aligned with the optical axis during a lithography process. The DOE 400 further includes two pairs of radiation-transmitting regions defined in the plate 402.

A first pair of radiation-transmitting regions 410 and 412 are positioned in an diametrical axis (e.g., x-axis) and on opposite sides of the optical axis at a center. The radiation-transmitting regions 410 and 412 may be equally distanced from the center of the DOE 400. The first pair 410 and 412 may be referred to as an extreme dipole corresponding to an outer sigma value and an inner sigma value. In the present embodiment, the first pair 410 and 412 may correspond to an outer sigma value ranging from about 0.80 to about 0.99 and an inner sigma value ranging from about 0.70 to about 0.89. In one embodiment, the first pair 410 and 412 may correspond to an outer sigma/inner sigma of about 0.90/0.81. In another embodiment, the first pair 410 and 412 may correspond to an outer sigma/inner sigma of about 0.83/0.73 (see FIG. 3). A second pair of radiation-transmitting regions 420 and 422 are positioned in the same diametrical axis (e.g., x-axis) and on opposite sides of the optical axis. Additionally, the second pair 420 and 422 are disposed between the radiation-transmitting regions 410 and 412 of the first pair. The radiation-transmitting regions 420 and 422 may be equally distanced from the center of the DOE 400. The second pair 420 and 422 may be referred to as an ancillary dipole corresponding to an outer sigma value and an inner sigma value. The second pair 420 and 422 have an outer sigma ranging from about 0.20 to about 0.40 and an inner sigma ranging from about 0.01 to about 0.02. In the present embodiment, the second pair 420 and 422 may correspond to an outer sigma/inner sigma of about 0.30/0.20.

The radiation-transmitting region may be defined in various shapes such as square, trapezoid, circular, or other proper shapes. The radiation-transmitting region may be made of a transparent or translucent material, an opening, or an opening covered with a transmitting material such as glass, liquid crystal, polarizers, or combinations thereof, to utilize an adjustable transmittance. During a lithography exposing process, a first pair of radiation beams illuminates through the first pair of radiation-transmitting regions 410 and 412 for strong off-axis illumination, and a second pair of radiation beams illuminates through the second pair of radiation-transmitting regions 420 and 422 for weak off-axis illumination. The DOE 400 is designed and configured such that the first pair 410 and 412 (extreme dipole) properly transfers an image of dense patterns (similar to the one in region 202 of photomask 200 shown in FIG. 2), and the second pair 420 and 412 (ancillary dipole) properly transfers an image of isolated patterns (similar to the one in region 204 of photomask 200 shown in FIG. 2) without adversely effecting the image of the dense patterns. Accordingly, the DOE 400 with the extreme dipole and ancillary dipole can properly transfer both dense patterns and isolated patterns of a photomask.

Referring to FIG. 5, illustrated is another exemplary embodiment of an DOE 500 that can be incorporated in the lithography system 100 of FIG. 1. The DOE 500 is similar to the DOE 400 of FIG. 4 except for the differences discussed below. Accordingly, similar features in FIGS. 4 and 5 are number the same for the sake of simplicity and clarity. The DOE 500 includes an extreme dipole (radiation-transmitting regions 410 and 412) and an ancillary dipole (radiation-transmitting regions 520 and 522) located in the x-axis. The radiation-transmitting regions 520 and 522 of the ancillary dipole correspond to an outer sigma value of about 0.30 and an inner sigma value of about 0.10. The performance of the DOE 500 to properly transfer images of both dense patterns and isolated patterns of a photomask is similar to the DOE 400 of FIG. 4.

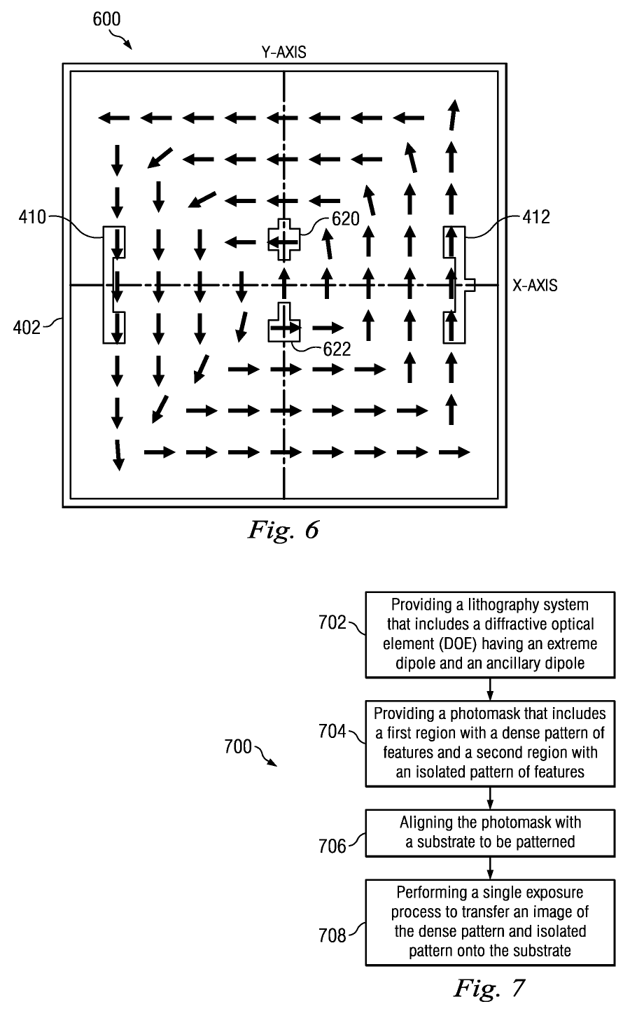

Referring to FIG. 6, illustrated is another exemplary embodiment of an DOE 600 that can be incorporated in the lithography system 100 of FIG. 1. The DOE 600 is similar to the DOE 500 of FIG. 5 except for the differences discussed below. Accordingly, similar features in FIGS. 5 and 6 are number the same for the sake of simplicity and clarity. The DOE 600 includes an extreme dipole (radiation-transmitting regions 410 and 412) located in the x-axis and an ancillary dipole (radiation-transmitting regions 620 and 622) located in the y-axis (perpendicular the x-axis). The radiation-transmitting regions 620 and 622 of the ancillary dipole correspond to an outer sigma value of about 0.30 and an inner sigma value of about 0.10. The performance of the DOE 600 to properly transfer images of both dense patterns and isolated patterns of a photomask is similar to the DOE 500 of FIG. 5.

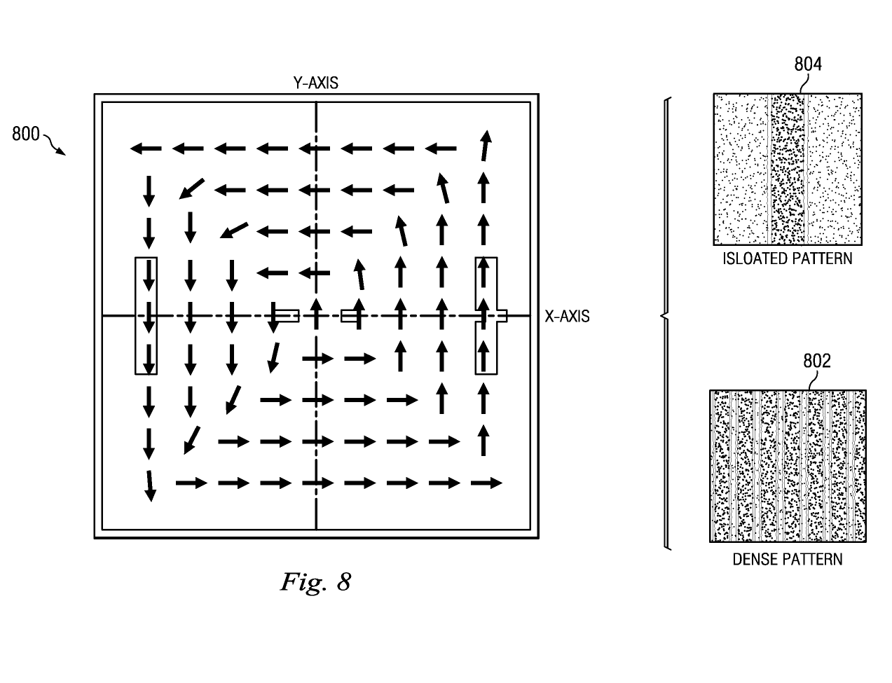

Referring to FIGS. 7 and 8, illustrated is a flow chart of an exemplary method 700 for patterning a substrate and a diagrammatic representation 800 thereof, respectively. The method 700 begins with block 702 in which a lithography system is provided that includes a diffractive optical element (DOE) having an extreme dipole and an ancillary dipole. The DOE may include the various embodiments 400, 500, 600 illustrated in FIGS. 4-6. The method 700 continues with block 704 in which a photomask is provided that includes a first region having a dense pattern of features and a second region having an isolated pattern of features. The photomask is similar to the one 200 illustrated in FIG. 2. The method 700 continues with block 706 in which the photomask is aligned with a substrate to be patterned. The method 700 continues with block 708 in which a single exposure process is performed to transfer an image of the dense pattern and the isolated pattern onto the substrate. In FIG. 8, the image of the dense pattern 802 and the isolated pattern 804 are both transferred onto the substrate in the single exposure. As shown in FIG. 8, photoresist residual defects are minimized on the isolated pattern 804 and CD uniformity is well controlled on the dense pattern 802 following a development process.

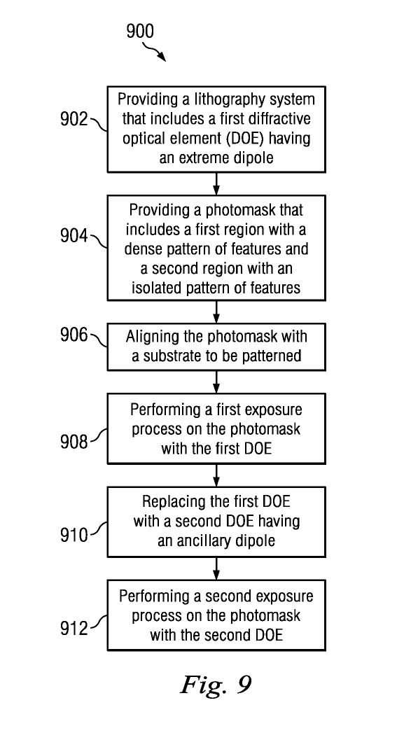

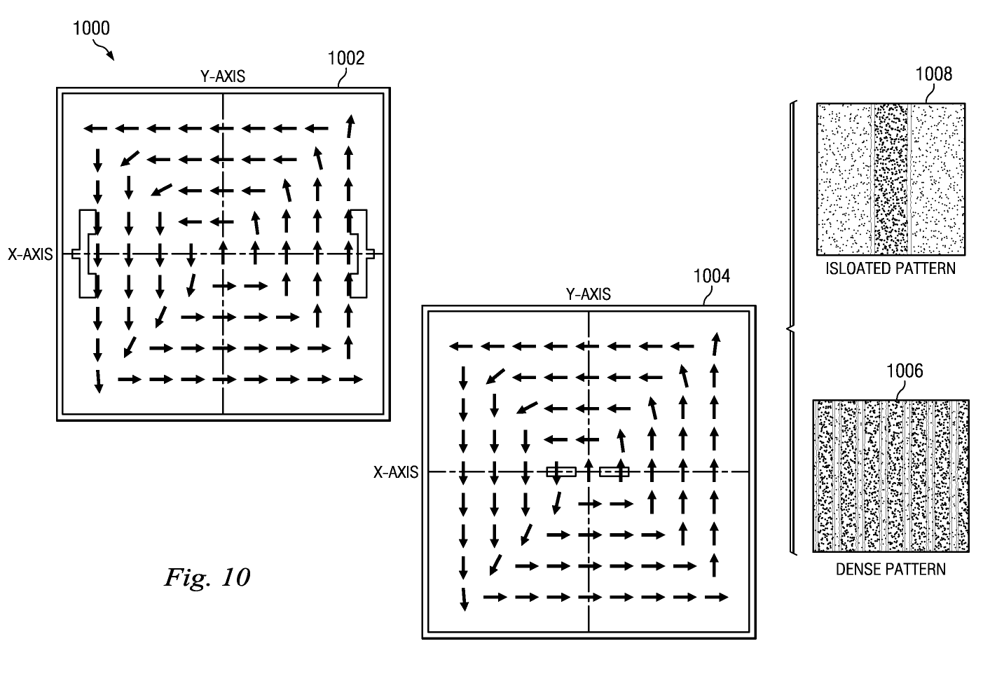

Referring to FIGS. 9 and 10, illustrated is a flow chart of another exemplary method 900 for patterning a substrate and a diagrammatic representation 1000 thereof, respectively. The method 900 begins with block 902 in which a lithography system is provided that includes a first diffractive optical element (DOE) having an extreme dipole. In FIG. 10, the DOE 1002 may include an extreme dipole located in the x-axis. The extreme dipole includes radiation-transmitting regions that correspond to outer and inner sigma values disclosed with reference to the embodiments of FIGS. 4-6. The method 900 continues with block 904 in which a photomask is provided that includes a first region having a dense pattern of features and a second region having an isolated pattern of features. The photomask is similar to the one 200 illustrated in FIG. 2. The method 900 continues with block 906 in which the photomask is aligned with a substrate to be patterned.

The method 900 continues with block 908 in which a first exposure process is performed on the photomask with the first DOE. In FIG. 10, the DOE 1002 properly transfers an image of the dense pattern 1006 onto the substrate. The method 900 continues with block 910 in which the first DOE is replaced with a second DOE having an ancillary dipole. In FIG. 10, the DOE 1004 may include an ancillary dipole located in the x-axis. In other embodiments, the ancillary dipole may optionally be located in the y-axis (perpendicular to the x-axis). The ancillary dipole may include radiation-transmitting regions that correspond to outer and inner sigma values disclosed with reference to the embodiments of FIGS. 4-6. The method 900 continues with block 912 in which a second exposure process is performed on the photomask with the second DOE. In FIG. 10. the DOE 1004 properly transfers an image of the isolated pattern 1008 onto the substrate without adversely effecting the image of the dense pattern 1006 on the substrate. Photoresist residual defects are minimized on the isolated pattern 1008 and CD uniformity is well controlled on the dense pattern 1006 following a development process. It should be noted that the first exposure process may be performed with the DOE having an ancillary dipole arrangement and the second exposure process may be performed with the DOE having an extreme dipole arrangement.

The present disclosure has been described relative to a preferred embodiment. Improvements or modifications that become apparent to persons of ordinary skill in the art only after reading this disclosure are deemed within the spirit and scope of the application. For example, the extreme dipole and ancillary dipole of the DOE may be structured in various configurations with respect to ring width, angle, sigma, and rotation of x-dipole and y-dipole. The combination of an extreme dipole for a strong off-axis illumination of dense patterns and an ancillary dipole for weak off-axis illumination of isolated patterns provides for relaxed design rules for pattern layouts, increased lithography process window, and decreased photoresist residual defects. It is understood that several modifications, changes and substitutions are intended in the foregoing disclosure and in some instances some features of the invention will be employed without a corresponding use of other features. Accordingly, it is appropriate that the appended claims be construed broadly and in a manner consistent with the scope of the invention.

What is claimed is:

1. A lithography system, comprising:
a source for providing energy;
an imaging system configured to direct the energy onto a substrate to form an image thereon; and
a diffractive optical element (DOE) incorporated with the imaging system, the DOE having a first dipole located in a first direction and a second dipole located in one of the first direction and a second direction perpendicular the first direction;
wherein the first dipole includes a first energy-transmitting region spaced a first distance from a center of the DOE, wherein the second dipole includes a second energy-transmitting region spaced a second distance from the center of the DOE, wherein the first distance is greater than the second distance.

2. The lithography system of claim 1, wherein the first energy-transmitting region includes an aperture corresponding to a first sigma inner value ranging from about 0.70 to about 0.89 and a first sigma outer value ranging from about 0.80 about 0.99.

3. The lithography system of claim 2, wherein the second energy-transmitting region includes an aperture corresponding to a second sigma inner value ranging from about 0.01 to about 0.20 and a second sigma outer value ranging from about 0.20 to about 0.40.

4. The lithography system of claim 3, wherein the second sigma outer value is about 0.30.

5. The lithography system of claim 4, wherein the second sigma inner value is about 0.20.

6. The lithography system of claim 4, wherein the second sigma inner value is about 0.10.

7. A lithography exposure method, comprising:
providing a lithography system that includes:
a source for providing energy;
an imaging system configured to direct the energy onto a substrate; and
a diffractive optical element (DOE) incorporated with the imaging system, the DOE having a first dipole located in a first direction and a second dipole located in one of the first direction and a second direction perpendicular the first direction, wherein the first dipole includes a first energy-transmitting region spaced a first distance from a center of the DOE, wherein the second dipole includes a second energy-transmitting region spaced a second distance from the center of the DOE, wherein the first distance is greater than the second distance;
aligning a photomask with the substrate; and
performing an exposure process with the lithography system such that an image of the photomask is transferred onto the substrate.

8. The method of claim 7, wherein providing the lithography system includes configuring the first energy-transmitting region to have an aperture corresponding to a first sigma inner value ranging from about 0.70 to about 0.89 and a first sigma outer value ranging from about 0.80 about 0.99.

9. The method of claim 8, wherein providing the lithography system includes configuring the second energy-transmitting region to have an aperture corresponding to a second sigma inner value ranging from about 0.01 to about 0.20 and a second sigma outer value ranging from about 0.20 to about 0.40.

10. The method of claim 9, wherein configuring the second energy-transmitting region includes selecting the second sigma inner value of about 0.20 and the second sigma outer value of about 0.30.

11. The method of claim 9, wherein configuring the second energy-transmitting region includes selecting the second sigma inner value of about 0.10 and the second sigma outer value of about 0.30.

12. The method of claim 7, further comprising providing the photomask having a first region and a second region, wherein the first region includes a dense pattern of features having a pitch not less than 80 nm, wherein the second region includes an isolated pattern of features having a spacing ranging from about 60 nm to about 200 nm.

13. A method for lithography processing in a lithography system, comprising:
providing a photomask having a first region and a second region, the first region including a dense pattern of features with a pitch not less than 80 nm, the second region including an isolated pattern of features with a spacing ranging from about 60 nm to about 200 nm; and
performing an exposure process with the lithography system to transfer the dense pattern of features and the isolated pattern of features onto a substrate;
wherein performing the exposure process includes one of:
performing a single exposure process with a dual dipole diffractive optical element (DOE) having a first dipole structure aligned in a first direction and a second dipole structure aligned in one of the first direction and a second direction perpendicular the first direction; and
performing a double exposure process including a first exposure with a first single dipole DOE having one of the first dipole structure and the second dipole structure and a second exposure process with a second single dipole DOE having the other one of the first dipole structure and the second dipole structure.

14. The method of claim 13, wherein the first dipole structure includes first apertures corresponding to a first sigma inner value ranging from about 0.70 to about 0.89 and a first sigma outer value ranging from about 0.80 about 0.99.

15. The method of claim 14, wherein the second dipole structure includes second apertures corresponding to a second sigma inner value ranging from about 0.01 to about 0.20 and a second sigma outer value ranging from about 0.20 to about 0.40.

16. The method of claim 15, wherein the second apertures correspond to a second sigma inner value of about 0.10 and a second sigma outer value of about 0.30.

17. The method of claim 15, wherein the second apertures correspond to a second sigma inner value of about 0.20 and a second sigma outer value of about 0.30.

18. The method of claim 13, wherein performing the exposure process includes performing the single exposure process;
wherein the first dipole structure includes an extreme dipole structure having radiation-transmitting regions each spaced a first distance from a center the dual dipole DOE, wherein the second dipole structure includes an ancillary dipole structure having radiation-transmitting regions each spaced a second distance from the center of the dual dipole DOE, wherein the first distance is greater than the second distance.

19. The method of claim 13, wherein performing the exposure process includes performing the double exposure process;
wherein the first dipole structure includes an extreme dipole structure having radiation-transmitting regions each spaced a first distance from a center of one of the first single dipole DOE and second single dipole DOE, wherein the second dipole structure includes an ancillary dipole structure having radiation-transmitting regions each spaced a second distance from the center of the other one of the first single dipole DOE and the second single dipole DOE, wherein the first distanced is greater than the second distance.

20. The method of claim 13, wherein providing the photomask includes providing a dense pattern of lines and an isolated pattern of lines.
